(19) United States
(12) Patent Application Publication
(10) Pub. No.: US 2025/0354270 A1
(43) Pub. Date: Nov. 20, 2025

(54) COMPOSITION, METHOD OF TREATING METAL-CONTAINING LAYER USING THE SAME, AND METHOD OF MANUFACTURING SEMICONDUCTOR DEVICE USING THE SAME

(71) Applicants: Samsung Electronics Co., Ltd., Suwon-si (KR); KOREA ADVANCED INSTITUTE OF SCIENCE AND TECHNOLOGY, Daejeon (KR)

(72) Inventors: Byungjoon KANG, Suwon-si (KR); Myungeun SEO, Daejeon (KR); Junsu KANG, Daejeon (KR); Cheol HAM, Suwon-si (KR); Kyuyoung HWANG, Suwon-si (KR); Jimin YOO, Daejeon (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 19/210,549

(22) Filed: May 16, 2025

(30) Foreign Application Priority Data
May 17, 2024 (KR) 10-2024-0064803
May 14, 2025 (KR) 10-2025-0062817

(51) Int. Cl. C23F 1/16; H01L 21/3213

(52) U.S. Cl. CPC C23F 1/16; H01L 21/32134

(57) ABSTRACT

Provided are a composition, a method of treating a metal-containing layer by using the same, and/or a method of manufacturing a semiconductor device by using the same. The composition includes an oxidizing agent, an acid, and a selective etching inhibitor. The selective etching inhibitor may include a polymer including a first repeating unit represented by Formula 1, a second repeating unit represented by Formula 2, or any combination thereof. Descriptions of Formulae 1 and 2 are provided in the specification.

### CROSS-REFERENCE TO RELATED APPLICATION

This application is based on and claims priority under 35 U.S.C. § 119 to Korean Patent Applications Nos. 10-2024-0064803, filed on May 17, 2024 and 10-2025-0062817, filed on May 14, 2025 in the Korean Intellectual Property Office, the disclosure of which is incorporated by reference herein in its entirety.

### BACKGROUND

### 1. Field

The disclosure relates to a composition, a method of treating a metal-containing layer by using the same, and/or a method of manufacturing a semiconductor device by using the same.

### 2. Description of the Related Art

As consumers demand higher performance at affordable prices, increased integration and/or improved reliability of semiconductor devices may be advantageous. As the level of integration of semiconductor devices increases, damage to semiconductor device components during the manufacturing process may have a greater impact on the reliability/or and electrical characteristics of semiconductor memory devices. In particular, during the manufacturing processes of semiconductor devices, various processing operations such as etching, cleaning, and polishing may be performed on a certain layer (e.g. a metal-containing layer), and compositions having suitable etching rates and the like for more effective processing operations on metal-containing layers may be advantageous.

### SUMMARY

Provided are a composition having excellent etching selectivity and/or storage stability, a method of treating a metal-containing layer using the same, and/or a method of manufacturing a semiconductor device using the same.

Additional aspects will be set forth in part in the description which follows and, in part, will be apparent from the description, or may be learned by practice of the presented embodiments of the disclosure.

According to an embodiment of the disclosure, a composition may include an oxidizing agent, an acid, and a selective etching inhibitor.

The selective etching inhibitor may include a polymer including a first repeating unit represented by Formula 1, a second repeating unit represented by Formula 2, or any combination thereof:

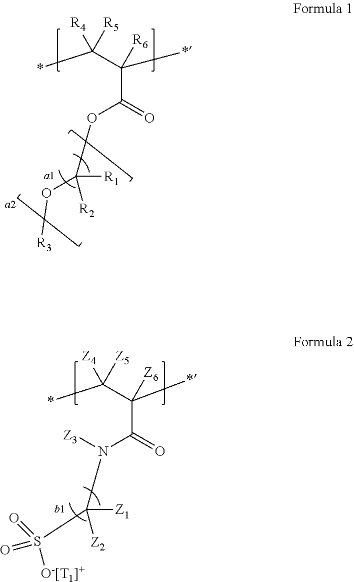

wherein, in Formulae 1 and 2,
T₁ may be hydrogen, alkali metal, or N(A₁)(A₂)(A₃)(A₄),
R₁ to R₆, Z₁ to Z₆ and A₁ to A₄ each independently may be
hydrogen, deuterium, *—F, *—OH, *—SH, *—C(═O)-Q₁, *—NH—C (═O)-Q₁, *—C(═O)—O-Q₁, or *—N(Q₁)(Q₂), or
a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, each unsubstituted or substituted with deuterium, *—F, *—OH, *—SH, *—C(═O)-Q₁₁, *—NH—C (═O)-Q₁₁, *—C(═O)—O-Q₁₁, *—N(Q₁₁)(Q₁₂), a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, or any combination thereof,
a1, a2, and b1 may each independently be an integer from 1 to 50,
Q₁, Q₂, Q₁₁ and Q₁₂ may each independently be
hydrogen, deuterium, *—F, *—OH, *—SH, *—C(═O)-Q₃, *—NH—C(═O)-Q₃, *—C(═O)—O-Q₃, or *—N(Q₃)(Q₄), or
a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, each unsubstituted or substituted with deuterium, *—F, *—OH, *—SH, *—C(═O)-Q₁₃, *—NH—C(═O)-Q₁₃, *—C(═O)—O-Q₁₃, *—N(Q₁₃)(Q₁₄), a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, or any combination thereof,
Q₃, Q₄, Q₁₃ and Q₁₄ are each independently hydrogen or a C₁-C₁₀ alkyl group, and

* and *′ each indicate a binding site to an adjacent repeating unit or a terminal group.

In some embodiments, the oxidizing agent may include hydrogen peroxide.

In some embodiments, the acid may include phosphoric acid.

In some embodiments, the selective etching inhibitor may include at least one of:
i) a homopolymer including the first repeating unit,
ii) a homopolymer including the second repeating unit,
iii) a copolymer including the first repeating unit and the second repeating unit,
iv) a copolymer including the second repeating unit and a third repeating unit, or
v) a copolymer including the first repeating unit, the second repeating unit, and the third repeating unit, or
vi) any combination thereof,

the third repeating unit may be a repeating unit derived from an unsaturated carboxylic acid-based monomer, and

the third repeating unit may be different from the first repeating unit.

In some embodiments, the selective etching inhibitor may include a copolymer including the first repeating unit and the second repeating unit, and the copolymer may be a block copolymer.

In some embodiments, T₁ in Formula 2 may be hydrogen, Na, K, or N(A₁)(A₂)(A₃)(A₄).

In some embodiments, R₁ to R₆, Z₁ to Z₆, and A₁ to A₄ each independently may be:
hydrogen, *—F, *—OH, or *—SH; or
a C₁-C₁₀ alkyl group, a C₁-C₁₀ alkoxy group, a C₁-C₁₀ alkylthio group, a C₂-C₁₀ alkenyl group, a cyclopentyl group, a cyclohexyl group, a phenyl group, a naphthyl group, a pyridinyl group, or a pyrimidinyl group, each unsubstituted or substituted with *—F, *—OH, *—SH, a C₁-C₁₀ alkyl group, a C₁-C₁₀ alkoxy group, a C₁-C₁₀ alkylthio group, a C₂-C₁₀ alkenyl group, a cyclopentyl group, a cyclohexyl group, a phenyl group, a naphthyl group, a pyridinyl group, or a pyrimidinyl group, or any combination thereof.

In some embodiments, a1 may be an integer from 2 to 5, and a2 may be an integer from 5 to 20.

In some embodiments, b1 may be an integer from 2 to 5.

In some embodiments, the first repeating unit may be represented by Formula 1A:

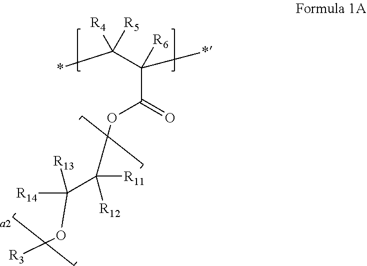

wherein, in Formula 1A,
R₃ to R₆ and a2 each may be the same as in Formula 1
R₁₁ to R₁₄ each independently may be the same as described in connection with R₁ in Formula 1, and
* and *′ each indicate a binding site to an adjacent repeating unit or a terminal group.

In some embodiments, the second repeating unit may be represented by Formula 2A:

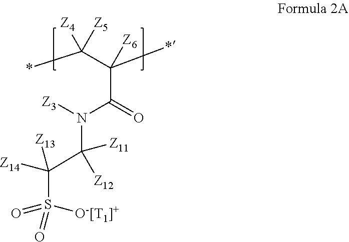

wherein, in Formula 2A,
Z₃ to Z₆ and T₁ each may be the same as described in Formula 2,
Z₁₁ to Z₁₄ each may be the same as described in connection with Z₁ in Formula 2, and
* and *′ each indicate a binding site to an adjacent repeating unit or a terminal group.

In some embodiments, a terminal group of a main chain of the polymer may be hydrogen, *—OH, or *—C (═O)—OH, or

a C₁-C₃₀ alkyl group or a C₁-C₃₀ alkoxy group, each unsubstituted or substituted with *—OH, *—C(═O)—OH, a C₁-C₃₀ alkyl group, a C₁-C₃₀ alkoxy group, or any combination thereof.

In some embodiments, an amount of the selective etching inhibitor may be about 0.001 wt % to about 20 wt % based on 100 wt % of the composition.

According to an embodiment of the disclosure, a method of treating a metal-containing layer may include
preparing a substrate on which a metal-containing layer is provided, and
contacting the metal-containing layer with the composition.

In some embodiments, a metal included in the metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), or copper (Cu), or any combination thereof.

In some embodiments, due to the contact between the metal-containing layer and the composition, at least a portion of the metal-containing layer may be etched, cleaned, or polished.

In some embodiments, the metal-containing layer may include a first region and a second region, and

during the contacting the metal-containing layer with the composition, the composition may etch the second region at a second etching rate and may etch the first region at a first etching rate. The second etching rate may be greater than the first etching rate.

According to an embodiment of the disclosure, a method of manufacturing a semiconductor device may include
preparing a substrate including a metal-containing layer thereon,
contacting the metal-containing layer with the composition, and

performing a subsequent manufacturing process to manufacture the semiconductor device.

### BRIEF DESCRIPTION OF THE DRAWINGS

These aspects, features, and advantages of certain embodiments of the disclosure will be more apparent from the following description taken in conjunction with the accompanying drawings, in which:

FIG. 1 shows a process flow diagram of an example of a method of manufacturing a semiconductor device; and

FIGS. 2 and 3 show diagrams briefly illustrating an embodiment of a metal-containing layer etching method.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the singular forms “a,” “an” and “the” are intended to include the plural forms as well, unless the context clearly indicates otherwise.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

### Metal-Containing Layer

A metal included in a metal-containing layer may be an alkali metal (for example, sodium (Na), potassium (K), rubidium (Rb), cesium (Cs), or the like), an alkaline earth metal (for example, beryllium (Be), magnesium (Mg), calcium (Ca), strontium (Sr), barium (Ba), or the like), a lanthanide metal (for example, lanthanum (La), europium (Eu), terbium (Tb), ytterbium (Yb), or the like), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), or the like), a post-transition metal (for example aluminum (Al), gallium (Ga), indium (In), thallium (TI), tin (Sn), or bismuth (Bi), or the like, or any combination thereof.

According to an embodiment, a metal included in a metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), or copper (Cu), or any combination thereof.

For example, the metal-containing layer may include aluminum, titanium, lanthanum, tungsten, or molybdenum or any combination thereof.

In some embodiments, the metal-containing layer may include titanium and tungsten.

In some embodiments, the metal-containing layer may include titanium and molybdenum.

The metal-containing layer may include a metal, a metal nitride, a metal oxide, or a metal oxynitride, or any combination thereof.

In an embodiment, the metal-containing layer may include a metal, a metal nitride, a metal oxide, or a metal oxynitride, or any combination thereof, and each of the metal, the metal of the metal nitride, the metal of the metal oxide, and the metal of the metal oxynitride may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), or copper (Cu), or any combination thereof.

In some embodiments, the metal-containing layer may include a metal nitride. The metal included in the metal nitride may include indium, titanium, aluminum, lanthanum, scandium, gallium, zinc, or hafnium, or any combination thereof.

For example, the metal-containing layer may include titanium nitride. The titanium nitride may further include indium, aluminum, lanthanum, scandium, gallium, hafnium, zinc, or tungsten, or any combination thereof. In some embodiments, the metal-containing layer may include titanium nitride, titanium nitride further including aluminum (e.g., titanium/aluminum nitride or TiAlN), and/or titanium nitride further including lanthanum, etc.

In some embodiments, the metal-containing layer may include a metal oxide. The metal included in the metal oxide may include titanium, aluminum, lanthanum, scandium, gallium, or hafnium, or any combination thereof. For example, the metal-containing layer may include one or more of aluminum oxide (for example, Al₂O₃), indium gallium zinc oxide (IGZO), or the like.

In some embodiments, the metal-containing layer may include the metal nitride and the metal oxide.

In some embodiments, the metal-containing layer may further include, in addition to the metal, a metalloid (for example, boron (B), silicon (Si), germanium (Ge), arsenic (As), antimony (Sb), tellurium (Te), or the like), a non-metal (for example, nitrogen (N), phosphorus (P), oxygen (O), sulfur(S), or selenium (Se), or the like), and any combination thereof.

For example, the metal-containing layer may further include silicon oxide.

The metal-containing layer may have a single-layer structure including one or more types of materials, or a multi-layer structure or three-dimensional pattern structure including different materials.

According to an embodiment, the metal-containing layer may include a first region and a second region, and a second etching rate at which the composition etches the second region may be greater than a first etching rate at which the composition etches the first region. During a treatment process (e.g., etching, cleaning and/or polishing process, or the like) for the metal-containing layer, at least a portion of the first region and at least a portion of the second region may each come into contact with the composition, and because the second etching rate is greater than the first etching rate, the second region may be etched faster than the first region.

For example, the first region may include a metal, a metal oxide (e.g., aluminum oxide), or silicon oxide, or any combination thereof.

According to an embodiment, the first region may include at least one of tungsten and molybdenum.

In some embodiments, the second region may include a metal nitride.

In some embodiments, the second region may include i) titanium nitride, ii) titanium nitride further including indium, aluminum, lanthanum, scandium, gallium, zinc, or hafnium, or any combination thereof (e.g., TiAlN), or iii) any combination thereof.

In some embodiments, each of the first region and the second region may include i) titanium nitride, ii) titanium nitride further including indium, aluminum, lanthanum, scandium, gallium, zinc, or hafnium, or any combination thereof, or iii) a combination thereof.

In some embodiments, the first region may include at least one of tungsten and molybdenum, and the second region may not include tungsten and molybdenum.

In some embodiments, the first region may include at least one of tungsten and molybdenum, and the second region may include i) titanium nitride, ii) titanium nitride further including indium, aluminum, lanthanum, scandium, gallium, zinc, or hafnium, or any combination thereof (e.g., TiAlN), or iii) a combination thereof.

In some embodiments, the first region may include at least one of tungsten and molybdenum, and the second region may include titanium nitride, titanium nitride further including aluminum (TiAlN), or any combination thereof.

In some embodiments, the first region may include at least one of a tungsten layer and a molybdenum layer, and the second region may include a titanium nitride layer, a titanium nitride layer further including aluminum (e.g., a titanium/aluminum nitride layer or a TiAlN layer), or any combination thereof.

In some embodiments, the first region may be a tungsten layer, and the second region may be a titanium nitride layer or a titanium nitride layer further including aluminum (e.g., a titanium/aluminum nitride layer or a TiAlN layer).

In some embodiments, the first region may be a molybdenum layer, and the second region may be a titanium nitride layer or a titanium nitride layer further including aluminum (e.g., a titanium/aluminum nitride layer or a TiAlN layer).

Etching of a layer herein may refer to the removal of at least a portion of a material constituting the layer.

### Composition

The composition may include an oxidizing agent, an acid, and a selective etching inhibitor.

The composition may be used in various treatment processes for the metal-containing layer described herein, for example, an etching process, a cleaning process, a polishing process, or the like.

The composition may further include water.

According to an embodiment, the composition may not include any organic acids. Although not intended to be limited by a specific theory, an organic acid may cause an unnecessary side reaction with the oxidizing agent included in the composition, thereby reducing the storage stability of the composition.

### Oxidizing Agent

The oxidizing agent may etch at least a portion of the metal-containing layer and may include, for example, at least one of hydrogen peroxide, nitric acid, and ammonium sulfate.

In an embodiment, the oxidizing agent may include hydrogen peroxide.

In some embodiments, the oxidizing agent may be hydrogen peroxide.

The amount (weight) of the oxidizing agent may be, for example, based on 100 wt % of the composition, about 0.001 wt % to about 50 wt %, about 0.01 wt % to about 50 wt %, about 0.1 wt % to about 50 wt %, about 0.5 wt % to about 50 wt %, about 1 wt % to about 50 wt %, about 0.001 wt % to about 30 wt %, about 0.01 wt % to about 30 wt %, about 0.1 wt % to about 30 wt %, about 0.5 wt % to about 30 wt %, about 1 wt % to about 30 wt %, about 0.001 wt % to about 20 wt %, about 0.01 wt % to about 20 wt %, about 0.1 wt % to about 20 wt %, about 0.5 wt % to about 20 wt %, about 1 wt % to about 20 wt %, about 0.001 wt % to about 10 wt %, about 0.01 wt % to about 10 wt %, about 0.1 wt % to about 10 wt %, about 0.5 wt % to about 10 wt %, about 1 wt % to about 10 wt %, about 1 wt % to about 6 wt %, or about 2 wt % to about 6 wt %.

### Acid

The acid, together with the oxidizing agent, may etch at least a portion of the metal-containing layer.

The acid may include an inorganic acid, an organic acid, or any combination thereof.

In an embodiment, the acid may include a phosphorus-based inorganic acid, a chlorine-based inorganic acid, a fluorine-based inorganic acid, or any combination thereof. For example, the phosphorus-based inorganic acid may be a phosphate-based inorganic acid.

In some embodiments, the acid may not include nitric acid, sulfuric acid, or any combination thereof.

In some embodiments, the acid may include a phosphate-based inorganic acid, a chlorine-based inorganic acid, or any combination thereof.

According to another embodiment, the acid may include phosphoric acid, hydrochloric acid, chloric acid, or any combination thereof.

In some embodiments, the acid may include a phosphoric acid.

The amount (weight) of the acid may be, for example, based on 100 wt % of the composition, about 0.01 wt % to about 90 wt %, about 0.1 wt % to about 90 wt %, about 1 wt % to about 90 wt %, about 10 wt % to about 90 wt %, about 20 wt % to about 90 wt %, about 30 wt % to about 90 wt %, about 40 wt % to about 90 wt %, about 50 wt % to about 90 wt %, about 60 wt % to about 90 wt %, about 0.01 wt % to about 80 wt %, about 0.1 wt % to about 80 wt %, about 1 wt % to about 80 wt %, about 10 wt % to about 80 wt %, about 20 wt % to about 80 wt %, about 30 wt % to about 80 wt %, about 40 wt % to about 80 wt %, about 50 wt % to about 80 wt %, or about 60 wt % to about 80 wt %.

### Selective Etching Inhibitor

The selective etching inhibitor may interact with various metal atoms in the metal-containing layer, which is the target layer, to control the etching rate, or the like.

The selective etching inhibitor may include a polymer including a first repeating unit represented by Formula 1, a second repeating unit represented by Formula 2, or any combination thereof:

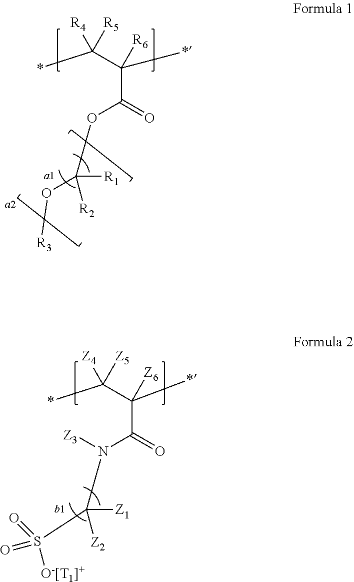

wherein, in Formulae 1 and 2,
T₁ may be hydrogen, alkali metal, or N(A₁)(A₂)(A₃)(A₄),
R₁ to R₆, Z₁ to Z₆ and A₁ to A₄ may each independently be:
hydrogen, deuterium, *—F, *—OH, *—SH, *—C(═O)-Q₁, *—NH—C(═O)-Q₁, *—C(═O)—O-Q₁, or *—N(Q₁)(Q₂); or
a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, each unsubstituted or substituted with deuterium, *—F, *—OH, *—SH, *—C(═O)-Q₁₁, *—NH—C (═O)-Q₁₁, *—C(═O)—O-Q₁₁, *—N(Q₁₁)(Q₁₂), a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, or any combination thereof, and
a1, a2, and b1 may each independently be an integer from 1 to 50,
Q₁, Q₂, Q₁₁, and Q₁₂ may each independently be:
hydrogen, deuterium, *—F, *—OH, *—SH, *—C(═O)-Q₃, *—NH—C(═O)-Q₃, *—C(═O)—O-Q₃, or *—N(Q₃)(Q₄), or
a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, each unsubstituted or substituted with deuterium, *—F, *—OH, *—SH, *—C(═O)-Q₁₃, *—NH—C(═O)-Q₁₃, *—C(═O)—O-Q₁₃, *—N(Q₁₃)(Q₁₄), a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, or any combination thereof,
Q₃, Q₄, Q₁₃ and Q₁₄ are each independently hydrogen or a C₁-C₁₀ alkyl group, and
* and *′ each indicate a binding site to an adjacent repeating unit or a terminal group.

The polymer has, as a side chain, the first repeating unit of Formula 1 and/or the second repeating unit of Formula 2, and thus enables excellent interaction with the metal atoms of the metal-containing layer, and thus can be usefully used in various treatment processes for the metal-containing layer. In addition, since the polymer is substantially not denatured even when mixed with an oxidizing agent, a composition including both the polymer and the oxidizing agent can have excellent storage stability, thereby contributing to improving the processability of metal-containing layer treatment. The first repeating unit and/or the second repeating unit each independently may be repeated a plurality of times (e.g., 2 to 100,000 times).

The polymer may be a water-soluble polymer.

For example, the polymer may include the first repeating unit.

In some embodiments, the polymer may include the second repeating unit.

In some embodiments, the polymer may include both the first repeating unit and the second repeating unit.

In an embodiment, the selective etching inhibitor may include at least one of:
i) a homopolymer including the first repeating unit,
ii) a homopolymer including the second repeating unit,
iii) a copolymer including the first repeating unit and the second repeating unit,
iv) a copolymer including the second repeating unit and a third repeating unit, or
v) a copolymer including the first repeating unit, the second repeating unit, and the third repeating unit, or
vi) any combination thereof,

The first repeating unit may be a repeating unit derived from an unsaturated carboxylic acid-based monomer. For example, the first repeating unit may be a repeating unit derived from poly (ethylene glycol) methyl ether methacrylate (PEGA where n is from 1 to 50).

The second repeating unit may be introduced using, for example, 2-arylamido-2-methyl-1-propanesulfonic acid (AMPS) (for example, Synthesis Examples 1 to 4).

The third repeating unit may be different from the first repeating unit and may be a repeating unit derived from an unsaturated carboxylic acid-based monomer.

For example, the unsaturated carboxylic acid-based monomer may include a polymerizable unsaturated group, such as a vinyl group.

In some embodiments, the unsaturated carboxylic acid-based monomer may include, for example, carboxyl group-containing vinyl compounds such as (meth) acrylic acid, itaconic acid, maleic acid, fumaric acid, crotonic acid, (meth) acrylic acid 2-carboxyethyl, etc.; unsaturated acid anhydrides such as maleic anhydride, itaconic anhydride, citraconic anhydride, etc.; half ester compounds of the unsaturated acid anhydrides and alkyl alcohols; and salts thereof.

In some embodiments, the selective etching inhibitor may include a copolymer including the first repeating unit and the second repeating unit, wherein the copolymer may be a random copolymer or a block copolymer.

In some embodiments, the selective etching inhibitor may include a copolymer including the first repeating unit and the second repeating unit, wherein the copolymer may be a block copolymer. When the copolymer is a block copolymer, a first block in which side chains of the first repeating unit are densely packed and a second block in which side chains of the second repeating unit are densely packed may be formed, and each of the first block and the second block effectively interacts with various metal atoms in the metal-containing layer, so that the etching rate of the metal-containing layer may be effectively controlled.

In some embodiments, T₁ in Formula 2 may be hydrogen, Na, K, or N(A₁)(A₂)(A₃)(A₄).

In some embodiments, R₁ to R₆, Z₁ to Z₆ and A₁ to A₄ in Formulae 1 and 2 may each independently be:
hydrogen, *—F, *—OH, or *—SH; or
a C₁-C₁₀ alkyl group, a C₁-C₁₀ alkoxy group, a C₁-C₁₀ alkylthio group, a C₂-C₁₀ alkenyl group, a cyclopentyl group, a cyclohexyl group, a phenyl group, a naphthyl group, a pyridinyl group, or a pyrimidinyl group, each unsubstituted or substituted with *—F, *—OH, *—SH, a C₁-C₁₀ alkyl group, a C₁-C₁₀ alkoxy group, a C₁-C₁₀ alkylthio group, a C₂-C₁₀ alkenyl group, a cyclopentyl group, a cyclohexyl group, a phenyl group, a naphthyl group, a pyridinyl group, or a pyrimidinyl group, or any combination thereof.

For example, R₁ to R₆, Z₁ to Z₆, and A₁ to A₄ in Formulae 1 and 2 may each independently be hydrogen or a C₁-C₁₀ alkyl group.

In some embodiments, a1 in Formula 1 may be an integer from 2 to 5, and a2 may be an integer from 5 to 20.

In some embodiments, b1 in Formula 2 may be an integer from 2 to 5.

In some embodiments, the main chain of the polymer may have a terminal group. For example, the terminal group of the main chain of the polymer may be:
hydrogen, *—OH, or *—C (═O)—OH; or
a C₁-C₃₀ alkyl group or a C₁-C₃₀ alkoxy group, each unsubstituted or substituted with *—OH, *—C(═O)—OH, a C₁-C₃₀ alkyl group, a C₁-C₃₀ alkoxy group, or any combination thereof.

In some embodiments, the first repeating unit may be represented by Formula 1A:

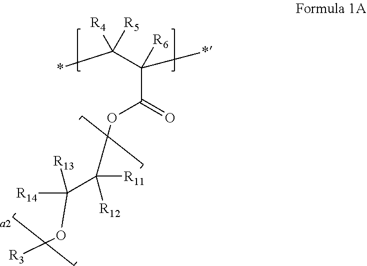

wherein, in Formula 1A,
R₃ to R₆ and a2 are each as described herein,
R₁₁ to R₁₄ are each as described in connection with R₁, and
* and *′ each indicate a binding site to an adjacent repeating unit or a terminal group.

According to another embodiment, the second repeating unit may be represented by Formula 2A:

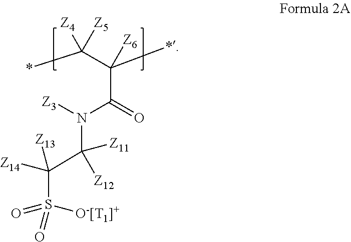

In Formula 2A,
Z₃ to Z₆ and T₁ are each as described herein,
Z₁₁ to Z₁₄ are each as described in connection with Z₁, and
* and *′ each indicate a binding site to an adjacent repeating unit or a terminal group.

A number average molecular weight of the polymer may be, for example, about 200 g/mol to about 1,000,000 g/mol, about 200 g/mol to about 500,000 g/mol, or about 200 g/mol to about 100,000 g/mol. The number average molecular weight may be measured, for example, using gel permeation chromatography (GPC), and may be a calculation value obtained using polystyrene.

In some embodiments, when the polymer is a homopolymer, a number average molecular weight of the homopolymer may be, for example, about 200 g/mol to about 1,000,000 g/mol, about 200 g/mol to about 100,000 g/mol, about 200 g/mol to about 10,000 g/mol, about 200 g/mol to about 7,000 g/mol, or about 300 g/mol to about 7,000 g/mol.

In some embodiments, when the polymer is a copolymer (for example, a block copolymer), a number average molecular weight of the copolymer may be, for example, about 200 g/mol to about 1,000,000 g/mol, about 200 g/mol to about 100,000 g/mol, about 200 g/mol to about 50,000 g/mol, about 200 g/mol to about 20,000 g/mol, about 200 g/mol to about 15,000 g/mol, about 500 g/mol to about 1,000,000 g/mol, about 500 g/mol to about 100,000 g/mol, about 500 g/mol to about 50,000 g/mol, about 500 g/mol to about 20,000 g/mol, about 500 g/mol to about 15,000 g/mol, 800 g/mol to about 1,000,000 g/mol, about 800 g/mol to about 100,000 g/mol, about 800 g/mol to about 50,000 g/mol, about 800 g/mol to about 20,000 g/mol, or about 800 g/mol to about 15,000 g/mol.

In some embodiments, the polymer may be one of polymers HP1, HP2, CP1, CP2 and CP3:

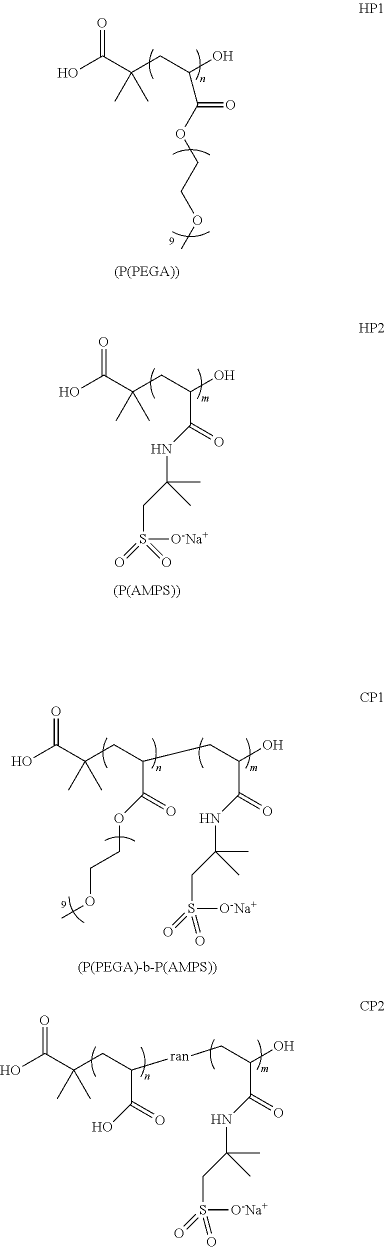

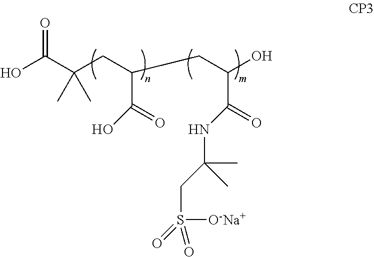

The polymers HP1 and HP2 are a homopolymer, the polymer CP1 and CP3 are a block copolymer and the polymer CP2 is a random copolymer.

n and m of the polymers HP1, HP2, CP1, CP2 and CP3 may each independently be selected from 2 to 100,000.

Each of the polymers HP1, HP2, CP1, CP2 and CP3 may have these ranges of number average molecular weight as described herein.

The amount (weight) of the polymer may be, on the basis of solids of the polymer, with respect to 100 wt % of the composition, for example, about 0.001 wt % to about 20 wt %, about 0.001 wt % to about 15 wt %, about 0.001 wt % to about 10 wt %, about 0.001 wt % to about 7 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.5 wt %, about 0.001 wt % to about 0.1 wt %, about 0.005 wt % to about 20 wt %, about 0.005 wt % to about 15 wt %, about 0.005 wt % to about 10 wt %, about 0.005 wt % to about 7 wt %, about 0.005 wt % to about 5 wt %, about 0.005 wt % to about 4 wt %, about 0.005 wt % to about 3 wt %, about 0.005 wt % to about 2 wt %, about 0.005 wt % to about 1 wt %, about 0.005 wt % to about 0.5 wt %, about 0.005 wt % to about 0.1 wt %, about 0.01 wt % to about 20 wt %, about 0.01 wt % to about 15 wt %, about 0.01 wt % to about 10 wt %, about 0.01 wt % to about 7 wt %, about 0.01 wt % to about 5 wt %, about 0.01 wt % to about 4 wt %, about 0.01 wt % to about 3 wt %, about 0.01 wt % to about 2 wt %, about 0.01 wt % to about 1 wt %, about 0.01 wt % to about 0.5 wt %, about 0.01 wt % to about 0.1 wt %, about 0.05 wt % to about 20 wt %, about 0.05 wt % to about 15 wt %, about 0.05 wt % to about 10 wt %, about 0.05 wt % to about 7 wt %, about 0.05 wt % to about 5 wt %, about 0.05 wt % to about 4 wt %, about 0.05 wt % to about 3 wt %, about 0.05 wt % to about 2 wt %, about 0.05 wt % to about 1 wt %, about 0.05 wt % to about 0.5 wt %, or about 0.05 wt % to about 0.1 wt %.

The selective etching inhibitor may further include an amine-containing compound in addition to the polymer described above. By further including the amine-containing compound, the etching rate and etching selectivity for the metal-containing layer may be further controlled.

In an embodiment, the amine-containing compound may include an alkylamine, an alkanolamine, or any combination thereof.

In some embodiments, the amine-containing compound may include a monoalkylamine (e.g., monobutylamine), a monoalkanolamine (e.g., ethanolamine), or any combination thereof.

In some embodiments, the amine-containing compound may include a compound represented by Formula 5:

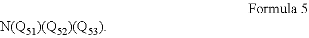

Q₅₁ to Q₅₃ in Formula 5 may each independently be:
hydrogen, deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), or *—N(CH₃)₂; or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), or *—N(CH₃)₂; a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof, and
at least one of Q₅₁ to Q₅₃ is not hydrogen.

For example, Q₅₁ to Q₅₃ in Formula 5 may each independently be:
hydrogen; or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), or *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof, and
at least one of Q₅₁ to Q₅₃ is not hydrogen.

In some embodiments, in Formula 5, Q₅₁ and Q₅₂ may each be hydrogen, and Q₅₃ may be a C₁-C₂₀ alkyl group; or a C₁-C₂₀ alkyl group substituted with *—F, *—OH, or any combination thereof.

When the selective etching inhibitor further includes an amine-containing compound, the weight ratio of the polymer to the amine-containing compound may be 1:0.01 to 1:10.

The amount (weight) of the selective etching inhibitor may be, for example, based on 100 wt % of the composition, about 0.001 wt % to about 20 wt %, about 0.001 wt % to about 15 wt %, about 0.001 wt % to about 10 wt %, about 0.001 wt % to about 7 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1.5 wt %, about 0.01 wt % to about 20 wt %, about 0.01 wt % to about 15 wt %, about 0.01 wt % to about 10 wt %, about 0.01 wt % to about 7 wt %, about 0.01 wt % to about 5 wt %, about 0.01 wt % to about 4 wt %, about 0.01 wt % to about 3 wt %, about 0.01 wt % to about 2 wt %, about 0.01 wt % to about 1.5 wt %, about 0.1 wt % to about 20 wt %, about 0.1 wt % to about 15 wt %, about 0.1 wt % to about 10 wt %, about 0.1 wt % to about 7 wt %, about 0.1 wt % to about 5 wt %, about 0.1 wt % to about 4 wt %, about 0.1 wt % to about 3 wt %, about 0.1 wt % to about 2 wt %, or about 0.1 wt % to about 1.5 wt %. In this regard, the amount of the polymer included in the selective etching inhibitor is evaluated on a solid basis.

According to an embodiment, in the composition, the amount of the oxidizing agent may be about 0.5 wt % to about 20 wt % based on 100 wt % of the composition, the amount of the acid may be about 30 wt % to about 80 wt % based on 100 wt % of the composition, and the amount of the selective etching inhibitor may be about 0.01 wt % to about 2 wt % based on 100 wt % of the composition.

The composition as described above may have a pH of about 1.0 to about 8.0, about 1.0 to about 7.0, about 1.0 to about 6.0, about 1.0 to about 5.0, about 1.0 to about 4.0, about 1.0 to about 3.0, about 2.0 to about 8.0, about 2.0 to about 7.0, about 2.0 to about 6.0, about 2.0 to about 5.0, about 2.0 to about 4.0, about 2.0 to about 3.0, about 3.0 to about 8.0, about 3.0 to about 7.0, about 3.0 to about 6.0, about 3.0 to about 5.0, about 3.0 to about 4.0, about 4.0 to about 8.0, about 4.0 to about 7.0, about 4.0 to about 6.0, about 4.0 to about 5.0, about 5.0 to about 8.0, about 5.0 to about 7.0, or about 5.0 to about 6.0. Since the composition has such pH ranges as described above, the interaction between the selective etching inhibitor and the metal atoms in the metal-containing layer, which will be described later, may be more smoothly achieved.

According to an embodiment, the composition may be used in a metal-containing layer treatment process, for example, an etching, cleaning and/or polishing process for a metal-containing layer. The metal-containing layer is as described herein.

In some embodiments, the composition may also be used as an etching by-product remover, a post-etch process by-product remover, an ashing process by-product remover, a cleaning composition, a photoresist (PR) remover, an etching composition for packaging process, a cleaner for packaging process, a wafer adhesive material remover, an etchant, a post-etch residue stripper, an ash residue cleaner, a photoresist residue stripper, a chemical mechanical polishing (CMP) cleaner, or a post-CMP cleaner.

Metal-containing layer treatment method and semiconductor device manufacturing method

A metal-containing layer may be effectively treated by using the composition described above.

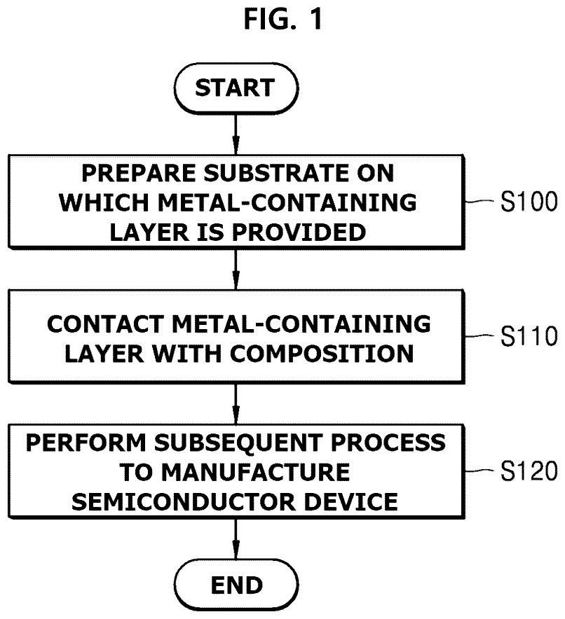

Referring to FIG. 1, an example of the method of treating a metal-containing layer may include: preparing a substrate on which a metal-containing layer is provided (S100); and contacting the metal-containing layer with a composition as described herein (S110).

The metal-containing layer is as described herein.

For example, metal included in the metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), or hafnium (Hf), copper (Cu), or any combination thereof.

In some embodiments, the metal-containing layer may include a metal, a metal nitride, a metal oxide, a metal oxynitride, or any combination thereof.

In some embodiments, the metal-containing layer may include a metal, a metal nitride, a metal oxide, a metal oxynitride, or any combination thereof, and each of the metal, the metal of the metal nitride, the metal of the metal oxide, and the metal of the metal oxynitride may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), or copper (Cu), or any combination thereof.

In some embodiments, the metal-containing layer may include titanium nitride.

In some embodiments, the metal-containing layer may include at least one of tungsten and molybdenum.

According to an embodiment, due to the contacting the metal-containing layer with the composition, at least a portion of the metal-containing layer may be etched, cleaned, or polished.

The polymer has, as a side chain, the first repeating unit of Formula 1 and/or the second repeating unit of Formula 2, and thus enables excellent interaction with the metal atoms of the metal-containing layer, and thus can be usefully used in various treatment processes for the metal-containing layer. In addition, since the polymer is substantially not denatured even when mixed with an oxidizing agent, a composition including both the polymer and the oxidizing agent can have excellent storage stability, thereby contributing to improving the processability of metal-containing layer treatment.

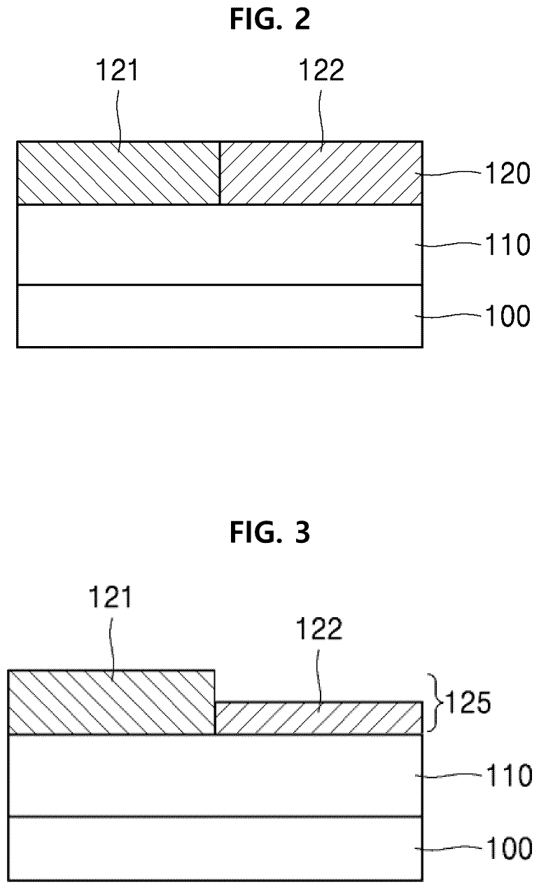

FIGS. 2 and 3 show diagrams briefly illustrating an embodiment of a metal-containing layer etching method.

Referring to FIG. 2, provided is a substrate 100 on which a metal-containing layer 120 is provided. An interlayer 110 may be positioned between the substrate 100 and the metal-containing layer 120. Although not shown in FIG. 2, circuitry elements (e.g., transistor gates, metal lines, impurity regions, semiconductor layers) may be arranged within the substrate 100, on the substrate 100, and/or between the substrate 100 and the interlayer 110. According to an embodiment, the metal-containing layer 120 may be directly positioned on the substrate 100, and the interlayer 110 may be omitted.

The metal-containing layer 120 may include a first region 121 and a second region 122. The second etching rate at which the composition etches the second region 122 may be greater than the first etching rate at which the composition etches the first region 121.

Referring to FIG. 3, the composition may be used to etch the metal-containing layer 120 to etch at least a portion of the first region 121 and at least a portion of the second region 122, thereby forming a metal-containing layer pattern 125. This process may be performed by contacting at least a portion of the first region 121 and at least a portion of the second region 122 with the composition.

The composition may etch each of at least a portion of the first region 121 and at least a portion of the second region 122. Referring to FIG. 3, the metal-containing layer pattern 125 formed after etching may include at least a portion of the second region 122, and various other modifications can be made, for example, in an embodiment, the etching process may be performed such that the second region 122 of the pattern of the metal-containing layer pattern 125 is completely removed, if necessary.

In some embodiments, the first region 121 may include at least one of tungsten and molybdenum.

In some embodiments, the second region 122 may include a metal nitride (e.g., titanium nitride).

In some embodiments, the second region 122 may include i) titanium nitride, ii) titanium nitride further including indium, aluminum, lanthanum, scandium, gallium, zinc, hafnium, or any combination thereof (e.g., TiAlN), or iii) a combination thereof.

In some embodiments, each of the first region 121 and the second region 122 may include i) titanium nitride, ii) titanium nitride further including indium, aluminum, lanthanum, scandium, gallium, zinc, hafnium, or any combination thereof, or iii) a combination thereof.

In some embodiments, the first region 121 may include at least one of tungsten and molybdenum, and the second region 122 may not include tungsten and molybdenum.

In some embodiments, the first region 121 may include at least one of tungsten and molybdenum, and the second region 122 may include i) titanium nitride, ii) titanium nitride further including indium, aluminum, lanthanum, scandium, gallium, zinc, hafnium, or any combination thereof (e.g., TiAlN), or iii) a combination thereof.

In some embodiments, the first region 121 may include at least one of tungsten and molybdenum, and the second region 122 may include titanium nitride, titanium nitride further including aluminum (e.g., TiAlN), or any combination thereof.

In some embodiments, the first region 121 may include at least one of a tungsten layer and a molybdenum layer, and the second region 122 may include a titanium nitride layer, a titanium nitride layer further including aluminum (e.g., a titanium/aluminum nitride layer or a TiAlN layer), or any combination thereof.

In some embodiments, the first region 121 may be a tungsten layer, and the second region 122 may be a titanium nitride layer or a titanium nitride layer further including aluminum (e.g., a titanium/aluminum nitride layer or a TiAlN layer).

In some embodiments, the first region 121 may be a molybdenum layer, and the second region 122 may be a titanium nitride layer or a titanium nitride layer further including aluminum (e.g., a titanium/aluminum nitride layer or a TiAlN layer).

Referring to FIG. 1, a method of manufacturing a semiconductor device according to an embodiment may include preparing a substrate on which a metal-containing layer is provided (S100); performing an etching process using the etching composition on the metal-containing layer to remove at least a portion of the metal-containing layer (S110); and performing a subsequent process to manufacture a semiconductor device (S120).

### SYNTHESIS EXAMPLE 1

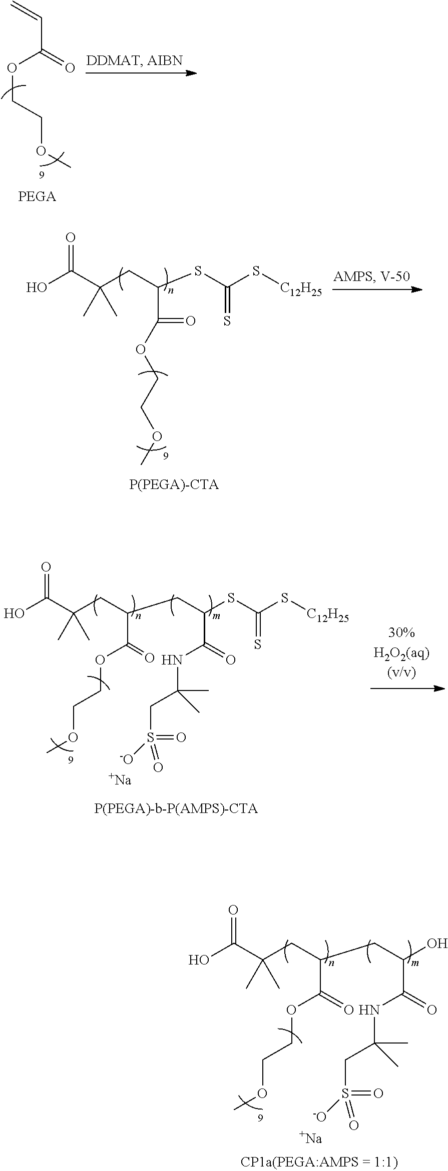

### Synthesis of P(PEGA)-CTA

In a 50 mL Schlenk flask, poly (ethylene glycol) methyl ether methacrylate (PEGA where n=9) (1.0 g, 2.1 mmol), 2-(dodecylthiocarbonothioylthio)-2-methylpropionic acid (DDMAT) (72.9 mg, 0.20 mmol), which is a chain transfer agent (CTA), 2,2′-azobis (2-methylpropionitrile) (AlBN) (6.57 mg, 0.040 mmol), and 2 mL of toluene were mixed, oxygen was removed therefrom through three freeze-pump-thaw cycles, sealed, and heated at 70° C. for 24 hours. After cooling to room temperature, the flask was opened to stop the reaction, dialyzed with methanol using a 3.5 kg/mol Mw cut off Spectra/por membrane (Spectrum, CA, US), the solvent was evaporated under reduced pressure, and dried under vacuum at 60° C. for 24 hours to synthesize P (PEGA)-CTA (Mn (predicted)=4930 kg/mol).

### Synthesis of P(PEGA)-b-P(AMPS)-CTA

In a 50 mL Schlenk flask, P (PEGA)-CTA (1.5 g, 0.30 mmol), 2-arylamido-2-methyl-1-propanesulfonic acid (AMPS) measured such that a weight ratio of the first monomer PEGA to the second monomer AMPS was 1:1, V-50 (Fujifilm product) (16.5 mg, 0.061 mmol), and 12 mL of ethanol were mixed, and oxygen was removed therefrom through three freeze-pump-thaw cycles, sealed, and heated at 70° C. for 24 hours. After cooling to room temperature, the flask was opened to stop the reaction, dialyzed with methanol using a 3.5 kg/mol Mw cut off Spectra/por membrane (Spectrum, CA, US), the solvent was evaporated under reduced pressure, and dried under vacuum at 60° C. for 24 hours to synthesize P (PEGA)-b-P (AMPS)-CTA (1.91 g, 63.8%, Mn (predicted)=9.89 kg/mol).

### Synthesis of CP1a

30 wt % aqueous H₂O₂ solution was added to the solution of the synthesized P(PEGA)-b-P(AMPS)-CTA (10 wt %) in water to replace the terminal group of P(PEGA)-b-P(AMPS)-CTA with a hydroxyl group, thereby synthesizing CP1a, which is a block copolymer having the backbone of CP1 in which a weight ratio of the first monomer PEGA to the second monomer AMPS is 1:1. The number average molecular weight of CP1a was evaluated through NMR spectroscopy and size exclusion chromatography (SEC) analysis, and confirmed to be 10,000 g/mol (9,890 g/mol).

### SYNTHESIS EXAMPLE 2

CP1b, which is a block copolymer having the backbone of CP1 in which a weight ratio of the first monomer PEGA to the second monomer AMPS is 1:2, was synthesized using the same method as Synthesis Example 1, except that AMPS, measured such that a weight ratio of the first monomer PEGA to the second monomer AMPS was 1:2, was used in the synthesis of P (PEGA)-b-P (AMPS)-CTA. The number average molecular weight of CP1b was evaluated through NMR spectroscopy and SEC analysis, and confirmed to be 15,000 g/mol.

### SYNTHESIS EXAMPLE 3

CP1c, which is a block copolymer having the backbone of CP1 in which a weight ratio of the first monomer PEGA to the second monomer AMPS is 2:5, was synthesized using the same method as Synthesis Example 1, except that AMPS, measured such that a weight ratio of the first monomer PEGA to the second monomer AMPS was 2:5, was used in the synthesis of P(PEGA)-b-P(AMPS)-CTA. The number average molecular weight of CP1c was evaluated through NMR spectroscopy and SEC analysis and was confirmed to be 7,500 g/mol.

### SYNTHESIS EXAMPLE 4

CP1d, which is a block copolymer having the backbone of CP1 in which a weight ratio of the first monomer PEGA to the second monomer AMPS is 7:5, was synthesized using the same method as Synthesis Example 1, except that AMPS, measured such that a weight ratio of the first monomer PEGA to the second monomer AMPS was 7:5, was used in the synthesis of P (PEGA)-b-P (AMPS)-CTA. The number average molecular weight of CP1d was evaluated through NMR spectroscopy and SEC analysis and was confirmed to be 12,000 g/mol.

### SYNTHESIS EXAMPLE 5

In a 100 mL Schlenk flask, the first monomer acrylic acid (0.1 g, 1.39 mmol), the second monomer AMPS (9.9 g, 47.7 mmol) and ammonium persulfate (0.11 g, 0.5 mmol) were dispersed in 25 mL of deionized water, and oxygen was removed therefrom through three freeze-pump-thaw cycles, and stirred at 70° C. for 24 hours. After confirming the formation of a white solid, the immersed white solid was quickly washed with methanol and water, passed through an ion exchange resin, and then dried in a vacuum for 24 hours to synthesize CP2 (a random copolymer) (Mn (predicted)=10,000 g/mol).

### EXAMPLES 1 to 6

Compositions of Examples 1 to 6 were prepared by mixing 4 wt % hydrogen peroxide as an oxidizing agent, 70 wt % phosphoric acid as an acid, and the selective etching inhibitor described in Table 1. The concentration of the polymer solid used as a selective etching inhibitor was adjusted to be 0.25 wt %, and the remainder of each composition corresponds to water (deionized water).

### Comparative Example A

A composition was prepared in the same manner as in Example 1, except that no oxidizing agent was used and the selective etching inhibitor described in Table 1 was used.

### Comparative Example B

A composition was prepared in the same manner as in Example 1, except that no selective etching inhibitor was used.

### Evaluation Example 1

The composition of Example 1 was placed in each of two beakers and heated to 70° C., and then the titanium nitride layer and the tungsten layer, which had undergone a plasma etching treatment, were each immersed in a beaker for 5 minutes, and then the thicknesses of the titanium nitride layer and the tungsten layer were measured using an ellipsometer (M-2000, JAWoolam), thereby evaluating the etching rate (A/min) of the composition of Example 1 for the titanium nitride layer and the etching rate (A/min) for the tungsten layer. Next, the etching rate for the titanium nitride layer was divided by the etching rate for the tungsten layer to evaluate R (TiN/W). Results thereof are summarized in Table 1.

The tests were repeated using the compositions of Examples 2 to 6 and Comparative Examples A and B. Results are summarized in Table 1.

TABLE 1

| | Selective etching inhibitor | | | | Etching | | |
|---|---|---|---|---|---|---|---|
| | | Weight ratio | Number | | rate for | Etching | |
| | | of the first | average | Presence | titanium | rate for | |
| | | monomer to | molecular | of | nitride | tungsten | |
| | | the second | weight | oxidizing | layer | layer | R(TiN/ |
| | Polymer | monomer | (g/mol) | agent | (Å/min) | (Å/min) | W) |
| Example 1 | HP1 | — | 5,000 | ◯ | 8.1 | 23.5 | 0.34 |
| Example 2 | HP2 | — | 5,000 | ◯ | 7.5 | 24.9 | 0.30 |
| Example 3 | CP1a | 1:1 | 10,000 | ◯ | 7.9 | 24.2 | 0.33 |
| Example 4 | CP1b | 1:2 | 15,000 | ◯ | 8.1 | 28.6 | 0.28 |
| Example 5 | CP1c | 2:5 | 7,500 | ◯ | 7.8 | 29.7 | 0.26 |
| Example 6 | CP1d | 7:5 | 12,000 | ◯ | 8.2 | 30.2 | 0.27 |
| Comparative | CP2 | 1:99 | 10,000 | X | 0 | 0 | 0 |
| Example A | | | | | | | |
| Comparative | — | — | — | ◯ | 7.8 | 33.6 | 0.23 |
| Example B | | | | | | | |

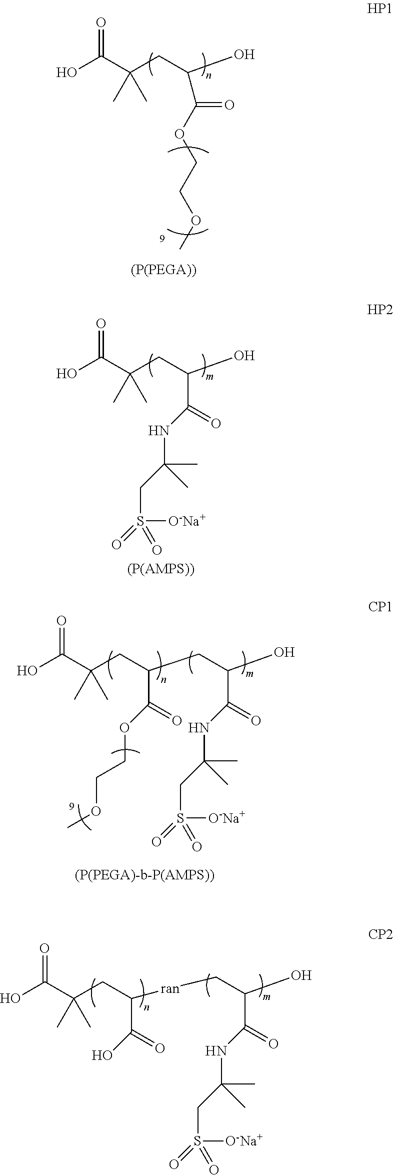

From Table 1, it can be confirmed that i) the composition of Comparative Example A without an oxidizing agent cannot etch the titanium nitride layer and the tungsten layer and ii) the compositions of Examples 1 to 6 can properly control the etching rate for tungsten layer and embody a high etching selectivity between the titanium nitride layer and the tungsten layer, compared to the composition of Comparative Example B.

### Evaluation Example 2

After the composition of Example 3 was stored at room temperature for 10 hours at pH<1 (sulfuric acid+nitric acid added), the presence or absence of denaturation of the polymer CP1a included in Example 3 was confirmed using 1H NMR analysis. As a result, it was confirmed that there was no denaturation of the molecular structure. From this, it can be confirmed that the composition of Example 3 has excellent storage stability.

The compositions according to embodiments have excellent etching selectivity and storage stability, and thus, can be effectively used in various processing processes for various metal-containing layers, such as etching, cleaning, and polishing processes. By processing a metal-containing layer using the composition, a higher-quality semiconductor device can be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition comprising
an oxidizing agent;
an acid; and
a selective etching inhibitor, wherein the selective etching inhibitor includes a polymer including a first repeating unit represented by Formula 1, a second repeating unit represented by Formula 2, or any combination thereof, 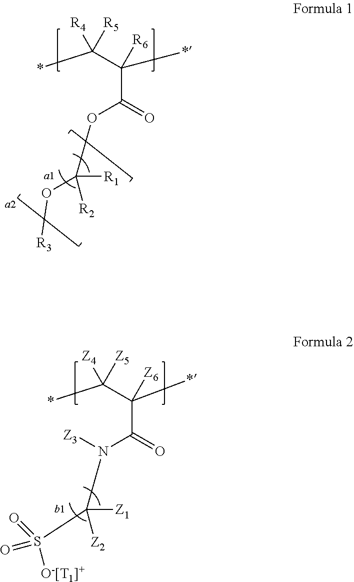
wherein, in Formulae 1 and 2,
T₁ is hydrogen, an alkali metal, or N(A₁)(A₂)(A₃)(A₄),
R₁ to R₆, Z₁ to Z₆, and A₁ to A₄ are each independently:
hydrogen, deuterium, *—F, *—OH, *—SH, *—C (=O)—Q₁, *—NH—C (=O)-Q₁, *—C (═O)—O—Q₁, or *—N(Q₁)(Q₂); or
a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, each unsubstituted or substituted with deuterium, *—F, *—OH, *—SH, *—C(═O)-Q₁₁, *—NH—C (═O)-Q₁₁, *—C(═O)—O-Q₁₁, *—N(Q₁₁)(Q₁₂), a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, or any combination thereof,
a1, a2, and b1 may each independently be an integer from 1 to 50,
Q₁, Q₂, Q₁₁ and Q₁₂ may each independently be
hydrogen, deuterium, *—F, *—OH, *—SH, *—C(═O)-Q₃, *—NH—C(═O)-Q₃, *—C(═O)—O-Q₃, or *—N(Q₃)(Q₄), or
a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, each unsubstituted or substituted with deuterium, *—F, *—OH, *—SH, *—C(═O)-Q₁₃, *—NH—C(═O)-Q₁₃, *—C(═O)—O-Q₁₃, *—N(Q₁₃)(Q₁₄), a C₁-C₃₀ alkyl group, a C₁-C₃₀ alkoxy group, a C₁-C₃₀ alkylthio group, a C₂-C₃₀ alkenyl group, a C₃-C₃₀ carbocyclic group, or a C₁-C₃₀ heterocyclic group, or any combination thereof,
Q₃, Q₄, Q₁₃ and Q₁₄ are each independently hydrogen or a C₁-C₁₀ alkyl group, and
* and *′ each indicate a binding site to an adjacent repeating unit or a terminal group.

2. The composition of claim 1, wherein
the oxidizing agent comprises hydrogen peroxide.

3. The composition of claim 1, wherein
the acid includes phosphoric acid.

4. The composition of claim 1, wherein
the selective etching inhibitor includes at least one of:
i) a homopolymer including the first repeating unit,
ii) a homopolymer including the second repeating unit,
iii) a copolymer including the first repeating unit and the second repeating unit,
iv) a copolymer including the second repeating unit and a third repeating unit, or
v) a copolymer including the first repeating unit, the second repeating unit, and the third repeating unit, or
vi) any combination thereof,
the third repeating unit is a repeating unit derived from an unsaturated carboxylic acid-based monomer, and
the third repeating unit is different from the first repeating unit.

5. The composition of claim 1, wherein
the selective etching inhibitor includes a copolymer including the first repeating unit and the second repeating unit, and
the copolymer is a block copolymer.

6. The composition of claim 1, wherein
T₁ in Formula 2 is hydrogen, Na, K, or N(A₁)(A₂)(A₃)(A₄).

7. The composition of claim 1, wherein
R₁ to R₆, Z₁ to Z₆, and A₁ to A₄ are each independently:
hydrogen, *—F, *—OH, or *—SH; or
a C₁-C₁₀ alkyl group, a C₁-C₁₀ alkoxy group, a C₁-C₁₀ alkylthio group, a C₂-C₁₀ alkenyl group, a cyclopentyl group, a cyclohexyl group, a phenyl group, a naphthyl group, a pyridinyl group, or a pyrimidinyl group, each unsubstituted or substituted with *—F, *—OH, *—SH, a C₁-C₁₀ alkyl group, a C₁-C₁₀ alkoxy group, a C₁-C₁₀ alkylthio group, a C₂-C₁₀ alkenyl group, a cyclopentyl group, a cyclohexyl group, a phenyl group, a naphthyl group, a pyridinyl group, or a pyrimidinyl group, or any combination thereof.

8. The composition of claim 1, wherein
a1 is an integer from 2 to 5, and
a2 is an integer from 5 to 20.

9. The composition of claim 1, wherein
b1 is an integer from 2 to 5.

10. The composition of claim 1, wherein
a terminal group of a main chain of the polymer is:
hydrogen, *—OH, or *—C(═O)—OH; or
a C₁-C₃₀ alkyl group or a C₁-C₃₀ alkoxy group, each unsubstituted or substituted with *—OH, *—C(═O)—OH, a C₁-C₃₀ alkyl group, a C₁-C₃₀ alkoxy group, or any combination thereof.

11. The composition of claim 1, wherein
the first repeating unit is represented by Formula 1A: 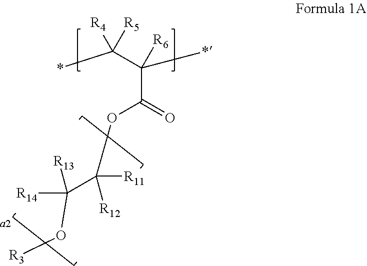
wherein, in Formula 1A,
R₅ to R₆ and a2 are each as described in Formula 1,
R₁₁ to R₁₄ are each as described in connection with R₁ in Formula 1, and
* and *′ each indicate a binding site to an adjacent repeating unit or a terminal group.

12. The composition of claim 1, wherein
the second repeating unit is represented by Formula 2A: 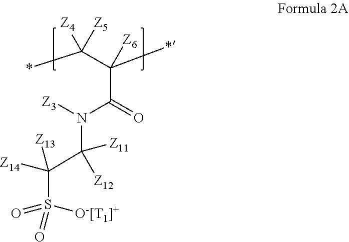
wherein, in Formula 2A,
Z₃ to Z₆ and T₁ are each as described in Formula 2,
Z₁₁ to Z₁₄ are each as described in connection with Z1 in Formula 2, and
* and *′ each indicate a binding site to an adjacent repeating unit or a terminal group.

13. The composition of claim 1, wherein
an amount of the selective etching inhibitor is about 0.001 wt % to about 20 wt %, based on 100 wt % of the composition.

14. A method of treating a metal-containing layer, comprising:
preparing a substrate including a metal-containing layer thereon; and
contacting the metal-containing layer with the composition of claim 1.

15. The method of claim 14, wherein
a metal included in the metal-containing layer comprises titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), or copper (Cu), or any combination thereof.

16. The method of claim 14, wherein
the metal-containing layer includes a metal, a metal nitride, a metal oxide, a metal oxynitride, or any combination thereof, and
the metal, the metal nitride, the metal oxide, and the metal oxynitride each independently include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), or copper (Cu), or any combination thereof.

17. The method of claim 14, wherein
due to the contacting the metal-containing layer and the composition, at least a portion of the metal-containing layer is etched, cleaned, or polished.

18. The method of claim 14, wherein
the metal-containing layer comprises a first region and a second region,
during the contacting the metal-containing layer with the composition, the composition etches the second region at a second etching rate and etches the first region at a first etching rate, and
the second etching rate is greater than the first etching rate.

19. The method of claim 18, wherein
the first region includes at least one of tungsten and molybdenum, and
the second region includes titanium nitride.

20. A method of manufacturing a semiconductor device, the method comprising:
preparing a substrate including a metal-containing layer thereon;
contacting the metal-containing layer with the composition of claim 1; and
performing a subsequent manufacturing process to manufacture the semiconductor device.
